(19) United States
(12) Patent Application Publication
(10) Pub. No.: US 2010/0319775 A1
(43) Pub. Date: Dec. 23, 2010

(54) Method and Apparatus for Annealing a Deposited Cadmium Stannate Layer

(75) Inventors: Scott Mills, Perrysburg, OH (US); Dale Roberts, Temperance, MI (US); David Eaglesham, Perrysburg, OH (US); Benyamin Buller, Sylvania, OH (US); Boil Pashmakov, Troy, MI (US); Zhibo Zhao, Novi, MI (US); Yu Yang, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/819,654

(22) Filed: Jun. 21, 2010

Related U.S. Application Data
(60) Provisional application No. 61/219,141, filed on Jun. 22, 2009.

(51) Int. Cl. H01L 31/0296; H01L 31/18

(52) U.S. Cl. 136/260; 438/84; 257/E31.015

(57) ABSTRACT

A method for manufacturing a multi-layered structure can include annealing a stack, where the annealing can include heating the stack in the presence of an inert gas, and where the stack includes a layer including cadmium and tin.

### CLAIM FOR PRIORITY

This application claims priority under 35 U.S.C. §119(e) to U.S. Provisional Patent Application Ser. No. 61/219,141 filed on Jun. 22, 2009, which is hereby incorporated by reference.

### TECHNICAL FIELD

The present invention relates to photovoltaic devices and methods of production.

### BACKGROUND

Photovoltaic devices can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic devices can also contain one or more transparent conductive oxide layers, which are also often conductors of electrical charge.

### DESCRIPTION OF DRAWINGS

FIG. 1 is a schematic of a photovoltaic device having multiple layers.

FIG. 2 is a schematic of a photovoltaic device having multiple layers.

FIG. 3 is a schematic of a photovoltaic device having multiple layers.

FIG. 4 is a schematic of a photovoltaic device having multiple layers.

FIG. 5 is a schematic of a photovoltaic device having multiple layers.

FIG. 6 is a schematic of a photovoltaic device having multiple layers.

### DETAILED DESCRIPTION

Photovoltaic devices can include multiple layers created on a substrate (or superstrate). For example, a photovoltaic device can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the device and/or all or a portion of the layer or substrate underlying the layer. For example, a “layer” can include any amount of any material that contacts all or a portion of a surface.

Photovoltaic devices can be formed on optically transparent substrates, such as glass. Because glass is not conductive, a transparent conductive oxide (TCO) layer is typically deposited between the substrate and the semiconductor bi-layer. Cadmium stannate functions well in this capacity, as it exhibits high optical transmission and low electrical sheet resistance. A smooth buffer layer can be deposited between the TCO layer and the semiconductor window layer to decrease the likelihood of irregularities occurring during the formation of the semiconductor window layer. Additionally, a barrier layer can be incorporated between the substrate and the TCO layer to lessen diffusion of sodium or other contaminants from the substrate to the semiconductor layers, which could result in degradation and delamination. The barrier layer can be transparent, thermally stable, with a reduced number of pin holes and having high sodium-blocking capability, and good adhesive properties. Therefore the TCO can be part of a three-layer stack, which may include, for example, a silicon dioxide barrier layer, a cadmium stannate TCO layer, and a buffer layer (e.g., a tin (IV) oxide). The buffer layer can include various suitable materials, including tin oxide, zinc tin oxide, zinc oxide, and zinc magnesium oxide.

A variety of barrier materials may be included in the TCO stack, including a silicon oxide and/or a silicon nitride. The TCO stack can include a silicon nitride, silicon oxide, aluminum-doped silicon oxide, boron-doped silicon nitride, phosphorus-doped silicon nitride, silicon oxide-nitride, or any combination or alloy thereof. The dopant can be less than 25%, less than 20%, less than 15%, less than 10%, less than 5% or less than 2%. The TCO stack may include multiple barrier materials. For example, the TCO stack can include a barrier bi-layer consisting essentially of a silicon oxide deposited over a silicon nitride (or an aluminum-doped silicon nitride). The barrier bi-layer can be optimized using optical modeling to achieve both color suppression and reduced reflection loss, though in practice a thicker bi-layer may be needed to block sodium more effectively. A tin oxide can be introduced as a control layer to enable proper cadmium stannate transformation in a nitrogen gas or low vacuum annealing process.

An amorphous layer including cadmium and tin can have any suitable thickness, for example, about 1000 to about 5000A. The layer can include any ratio of cadmium and tin suitable for a TCO. For example, the cadmium to tin ratio can be about 1.8:2.5. The cadmium and tin layer can also have any suitable roughness, for example less than about 20 nm, as well as any suitable average absorption, for example, more than about 10% in the range of about 400-850 nm. The sheet resistance of the cadmium and tin layer can be more than about 100 ohms/sq. The layer can be annealed for about 3 minutes to about 25 minutes at about 500 to about 700 C, transforming the layer into a cadmium stannate, with a sheet resistance of less than about 20 ohms/sq (for example, less than about 10 ohms/sq), with an average absorption of less than about 20% in the range of about 400-850 nm, and roughness less than about 1 nm. The layer can be annealed for about 5 minutes to about 20 minutes. The layer can be annealed for about 10 minutes to about 15 minutes. The layer can be annealed at about 600 degrees C.

In one aspect, a method for manufacturing a multi-layered structure can include annealing a stack. The annealing can include heating the stack in the presence of an inert gas. The stack can include a layer including cadmium and tin.

The inert gas can include a forming gas, a hydrogen gas, a nitrogen gas, a hydrogen and nitrogen gas mix, or an argon gas. The method can include depositing the layer including cadmium and tin on a substrate. The method can include forming a stack. The forming can include depositing one or more barrier layers on a substrate. The forming can include depositing the layer including cadmium and tin on the one or more barrier layers. The forming can include depositing a buffer layer on the layer including cadmium and tin. The method can include depositing a control layer on the layer including cadmium and tin prior to depositing a buffer layer. The depositing can include sputtering. The sputtering can include DC sputtering or AC dual magnetron sputtering. The depositing can include sputtering from an alloy target. The forming can occur under about 2 to 7 mtorr of pressure. The forming can occur under about 2.5 mtorr of pressure. The forming can occur under about 5 mtorr of pressure. The forming can occur in a vacuum. The annealing can include heating the stack for about 15 to 25 minutes at about 500 to 700 C. The annealing can include heating the stack for about 10 to 20 minutes at about 600 C. The heating can include radiated heating, convective heating, and/or resistive heating. Depositing one or more barrier layers can include depositing a silicon nitride directly on a substrate. Depositing one or more barrier layers can include depositing a silicon oxide. Depositing one or more barrier layers can include depositing an aluminum-doped silicon nitride directly on a substrate. Depositing one or more barrier layers can include depositing an aluminum-doped silicon oxide. Depositing one or more barrier layers can include depositing a silicon nitride directly on a substrate and a silicon oxide on the silicon nitride. Depositing one or more barrier layers can include depositing an aluminum-doped silicon nitride directly on a substrate and an aluminum-doped silicon oxide on the aluminum-doped silicon nitride. Depositing one or more barrier layers can include depositing a first silicon oxide on a substrate. Depositing one or more barrier layers can include depositing a silicon nitride on the first silicon oxide. Depositing one or more barrier layers can include depositing a second silicon oxide on the silicon nitride. Depositing one or more barrier layers can include depositing a first aluminum-doped silicon oxide on a substrate. Depositing one or more barrier layers can include depositing an aluminum-doped silicon nitride on the first aluminum-doped silicon oxide. Depositing one or more barrier layers can include depositing a second aluminum-doped silicon oxide on the aluminum-doped silicon nitride. Each of the one or more barrier layers can include silicon nitride, aluminum-doped silicon nitride, silicon oxide, aluminum-doped silicon oxide, boron-doped silicon nitride, phosphorous-doped silicon nitride, silicon oxide-nitride, and tin oxide. The buffer layer can include a zinc tin oxide, tin oxide, zinc oxide, and zinc magnesium oxide. The control layer can include a tin oxide. The method can include depositing a cadmium sulfide layer on the stack, and a cadmium telluride layer on the cadmium sulfide layer. The method can include depositing a cadmium sulfide layer on the stack, and a cadmium telluride layer on the cadmium sulfide layer.

In one aspect, a multilayered structure can include a stack of one or more layers, including a transparent conductive oxide layer. The stack can be annealed in the presence of an inert gas. The transparent conductive oxide layer includes a layer including cadmium and tin.

The stack can include a substrate. The stack can include one or more barrier layers. The stack can include a buffer layer. Each of the one or more barrier layers may be positioned above the substrate. The transparent conductive oxide layer may be positioned above the one or more barrier layers. The buffer layer may be positioned above the transparent conductive oxide layer. The buffer layer can include a zinc tin oxide, tin oxide, zinc oxide, and zinc magnesium oxide. Each of the one or more barrier layers can include a silicon nitride, aluminum-doped silicon nitride, silicon oxide, aluminum-doped silicon oxide, boron-doped silicon nitride, phosphorous-doped silicon nitride, silicon oxide-nitride, and tin oxide. The multilayered structure can include a cadmium sulfide layer on the stack, and a cadmium telluride layer on the cadmium sulfide layer.

In another aspect, a multilayered structure may include a substrate and an amorphous layer including cadmium and tin. The amorphous layer may have a sheet resistance of more than about 100 ohms/sq. In another aspect, a multilayered structure may include a substrate. The multilayered structure may include a layer including cadmium and tin on the substrate. The layer may have a sheet resistance of less than about 20 ohms/sq.

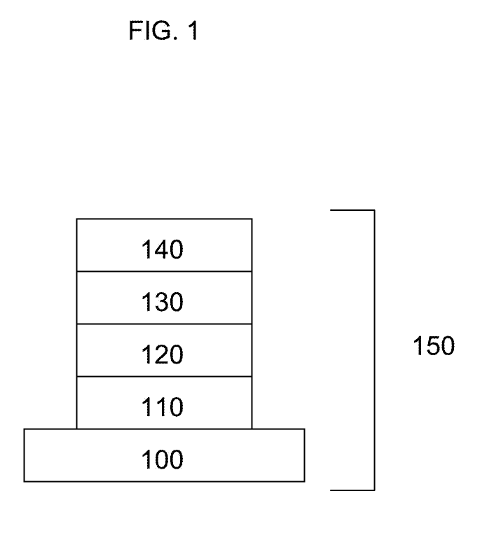

FIG. 1 shows a transparent conductive oxide stack 150 including a first barrier layer 110 on a substrate 100 (e.g., soda-lime glass). First barrier layer 110 can include any suitable barrier material including a silicon oxide, silicon nitride, aluminum-doped silicon oxide, or aluminum-doped silicon nitride. For example, first barrier layer 110 can include a silicon dioxide or a silicon nitride (e.g., Si₃N₄). Transparent conductive oxide layer 120 can be deposited adjacent to first barrier layer 110. Transparent conductive oxide layer 120 can include a layer including cadmium and tin and can be of any suitable thickness. For example, transparent conductive oxide layer 120 can have a thickness of about 100 nm to about 1000 nm. Transparent conductive oxide layer 120 can be deposited using any known deposition technique, including sputtering.

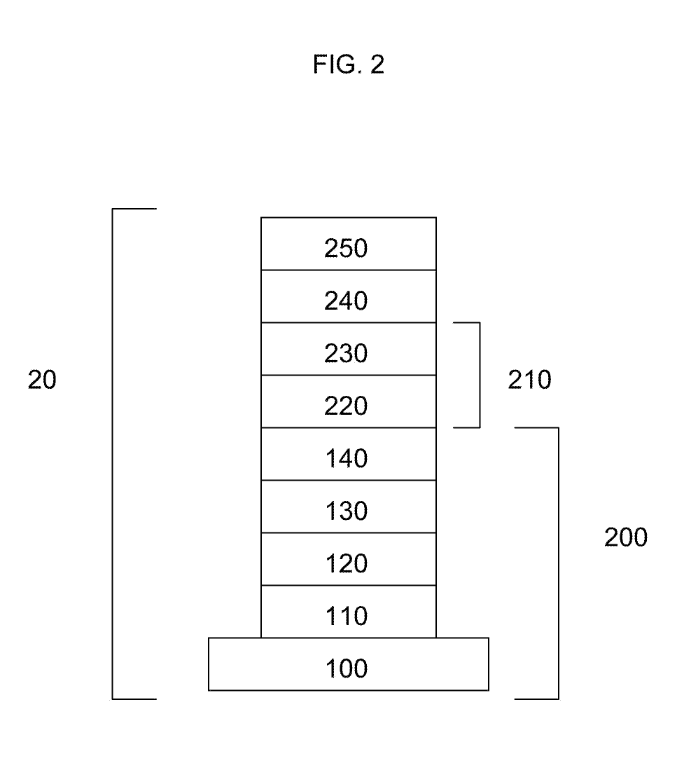

In continuing reference to FIG. 1, a control layer 130 can be deposited adjacent to transparent conductive oxide layer 120 to enable proper transformation of transparent conductive oxide layer 120 (i.e., from a layer including cadmium and tin to cadmium stannate). Control layer 130 can be deposited using any known deposition technique, including sputtering. Control layer 130 can include a tin oxide and can be of any suitable thickness. For example, control layer 130 can have a thickness of about 10 nm to about 100 nm. A buffer layer 140 can be deposited adjacent to control layer 130 to facilitate proper deposition of semiconductor window layer 220 from FIG. 2. Buffer layer 140 can be deposited using any known deposition technique, including sputtering. Buffer layer 140 can include a tin(IV) oxide and can be of any suitable thickness. For example, buffer layer 140 can have a thickness of about 10 nm to about 100 nm.

The TCO, barrier, control, and buffer layers can all be deposited at room temperature using any suitable sputtering process, including DC and AC sputtering, for example AC dual magnetron sputtering. A cadmium sulfide layer can be deposited on the stack using DC sputtering. The stack of layers can be deposited using an in-line sputtering process, and in a controlled environment. For example, the layers may be deposited in a vacuum or in the presence of an oxygen gas. The controlled environment can include 100% oxygen gas or substantially less. The layers can be deposited under any suitable pressure, including low pressure. For example, the layers can be deposited at about 2 to 7 mtorr. The layers can be deposited at about 2.5 mtorr. The layers can be deposited at about 5 mtorr. The TCO stack can be manufactured using a variety of deposition techniques, including for example, low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis. Each deposition layer can be of any suitable thickness, for example in the range of about 1 to about 5000A.

A sputtering target can be manufactured by ingot metallurgy. A sputtering target can be manufactured from cadmium, from tin, or from both cadmium and tin. The cadmium and tin can be present in the same target in stoichiometrically proper amounts. A sputtering target can be manufactured as a single piece in any suitable shape. A sputtering target can be a tube. A sputtering target can be manufactured by casting a metallic material into any suitable shape, such as a tube.

A sputtering target can be manufactured from more than one piece. A sputtering target can be manufactured from more than one piece of metal, for example, a piece of cadmium and a piece of tin. The cadmium and tin can be manufactured in any suitable shape, such as sleeves, and can be joined or connected in any suitable manner or configuration. For example, a piece of cadmium and a piece of tin can be welded together to form the sputtering target. One sleeve can be positioned within another sleeve.

A sputtering target can be manufactured by powder metallurgy. A sputtering target can be formed by consolidating metallic powder (e.g., cadmium or tin powder) to form the target. The metallic powder can be consolidated in any suitable process (e.g., pressing such as isostatic pressing) and in any suitable shape. The consolidating can occur at any suitable temperature. A sputtering target can be formed from metallic powder including more than one metal powder (e.g., cadmium and tin). More than one metallic powder can be present in stoichiometrically proper amounts.

A sputter target can be manufactured by positioning wire including target material adjacent to a base. For example wire including target material can be wrapped around a base tube. The wire can include multiple metals (e.g., cadmium and tin) present in stoichiometrically proper amounts. The base tube can be formed from a material that will not be sputtered. The wire can be pressed (e.g., by isostatic pressing).

A sputter target can be manufactured by spraying a target material onto a base. Metallic target material can be sprayed by any suitable spraying process, including thermal spraying and plasma spraying. The metallic target material can include multiple metals (e.g., cadmium and tin), present in stoichiometrically proper amounts. The base onto which the metallic target material is sprayed can be a tube.

Once the TCO, barrier, control, and buffer layers are deposited, the resulting stack(s) can be thrown into an annealing apparatus, such as an oven. The oven can be of any suitable size and/or capacity. For example, the oven can be equipped to process two or three stacks in parallel. The oven can also be configured to use various suitable methods of heating, including resistive heating, convective heating, and radiated heating. The oven can contain separate heat zones to control temperature. The entire heating element of the oven can be encased in a stainless steel sleeve that is hermetically sealed. The oven can include rollers to pass the stack(s) through the oven. The rollers can be made of any suitable material, including for example ceramic material. Bearings can be positioned on the walls of the oven to support the rollers. The rollers can be driven from the outside. The oven can include separate controls between the edges and center sections of the oven to control edge temperature.

One or more stacks can be thrown into and passed through the oven to undergo a single heating process. The heating can include a first ramp-up phase, where the temperature of the stack(s) is increased to achieve a soak temperature. It can take about 2 to 5 minutes for the soak temperature to be reached. The soak temperature can be anywhere from about 500 to about 700 C. For example, the soak temperature can be about 600 C. The stack(s) can be annealed in the presence of any suitable gas to control an aspect of the annealing. The stacks can be annealed in the presence of one or more inert gases, including for example, nitrogen gas, hydrogen gas, a nitrogen-hydrogen gas mix, and argon gas. The stacks can be annealed in any suitable concentration of one or more gases. For example, the stacks can be annealed in an environment including from about 100 ppm to about 5% of a hydrogen in nitrogen gas mixture, such as forming gas. Other examples of gases that can be used during the anneal process include flammable hydrocarbon gases, including alkanes such as methane, ethane, propane, butane, and other gases having the formula C₍ₙ₎H₍₂ₙ₊₂₎. Other examples of gases that can be used during the anneal process include alcohols such as methanol, ethanol, propanol, and butanol, and other acyclic alcohols having the formula C(ₙ)H(₂ₙ₊₁)OH.

At the end of the annealing process, the stack(s) can be quenched using any suitable technique, including nitrogen quenching. The stacks can also undergo other suitable rapid cool-down processes. Following the annealing step, device layers (e.g., cadmium sulfide and cadmium telluride) can be deposited on the stack(s) to form photovoltaic device(s).

Transparent conductive oxide stack 150 from FIG. 1 can be annealed to form annealed transparent conductive oxide stack 200 from FIG. 2. Transparent conductive oxide stack 150 can be annealed using any suitable annealing process. The annealing can occur in the presence of a gas selected to control an aspect of the annealing, for example nitrogen gas. Transparent conductive oxide stack 150 can be annealed under any suitable pressure, for example, under reduced pressure, in a low vacuum, or at about 0.01 Pa (10⁻⁴ Ton). Transparent conductive oxide stack 150 can be annealed at any suitable temperature or temperature range. For example, transparent conductive oxide stack 150 can be annealed at about 400° C. to about 800° C. Transparent conductive oxide stack 150 can be annealed at about 500° C. to about 700° C. Transparent conductive oxide stack 150 can be annealed for any suitable duration. Transparent conductive oxide stack 150 can be annealed for about 3 to about 25 minutes. Transparent conductive oxide stack 150 can be annealed for about 5 to about 20 minutes. Transparent conductive oxide stack 150 can be annealed for about 10 to about 15 minutes.

Annealed transparent conductive oxide stack 200 can be used to form photovoltaic device 20 from FIG. 2. Referring to FIG. 2, a semiconductor bi-layer 210 can be deposited adjacent to annealed transparent conductive oxide stack 200. Semiconductor bi-layer 210 can include a semiconductor window layer 220 and a semiconductor absorber layer 230. Semiconductor window layer 220 can be deposited adjacent to annealed transparent conductive oxide stack 200. Semiconductor window layer 220 can be deposited using any known deposition technique, including vapor transport deposition. Semiconductor absorber layer 230 can be deposited adjacent to semiconductor window layer 220. Semiconductor absorber layer 230 can be deposited using any known deposition technique, including vapor transport deposition. Semiconductor window layer 220 can include a cadmium sulfide layer. Semiconductor absorber layer 230 can include a cadmium telluride layer. A back contact 240 can be deposited adjacent to semiconductor bi-layer 210. Back contact 240 can be deposited adjacent to semiconductor absorber layer 230. A back support 250 can be deposited adjacent to back contact 240.

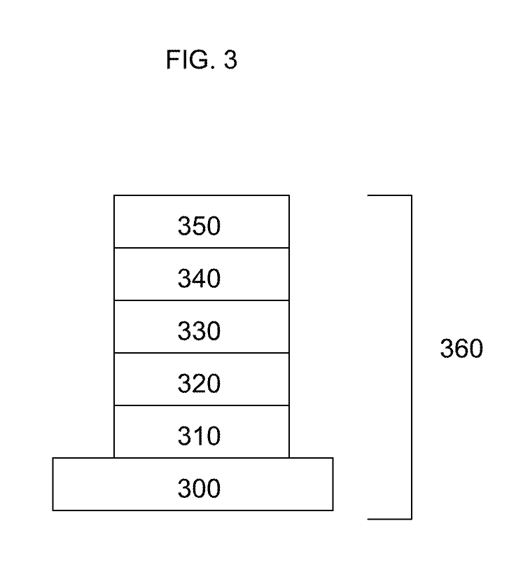

FIG. 3 shows an embodiment in which transparent conductive oxide stack 360 includes a first barrier layer 310 on a substrate 300, and a second barrier layer 320 on first barrier layer 310. Second barrier layer 320 can be deposited adjacent to first barrier layer 310. Second barrier layer 320 can be deposited using any known deposition technique, including sputtering. First barrier layer 310 can include any suitable barrier material, including a silicon nitride or an aluminum-doped silicon nitride. Second barrier layer 320 can include any suitable barrier material, including a silicon oxide or an aluminum-doped silicon oxide. Transparent conductive oxide stack 360 can include a silicon dioxide deposited over a silicon nitride (e.g., Si₃N₄). Transparent conductive oxide stack 360 can include an aluminum-doped silicon oxide deposited over an aluminum-doped silicon nitride. Deposition of aluminum-doped silicon oxide or silicon oxide over silicon nitride or aluminum-doped silicon nitride can prevent direct contact between the nitrogen and transparent conductive oxide layer 330, and thus ensure proper transformation of transparent conductive oxide layer 330 (e.g., transformation of cadmium and tin layer to cadmium stannate). First barrier layer 310 and second barrier layer 320 can be optimized using optical modeling to achieve both color suppression and reduced reflection loss.

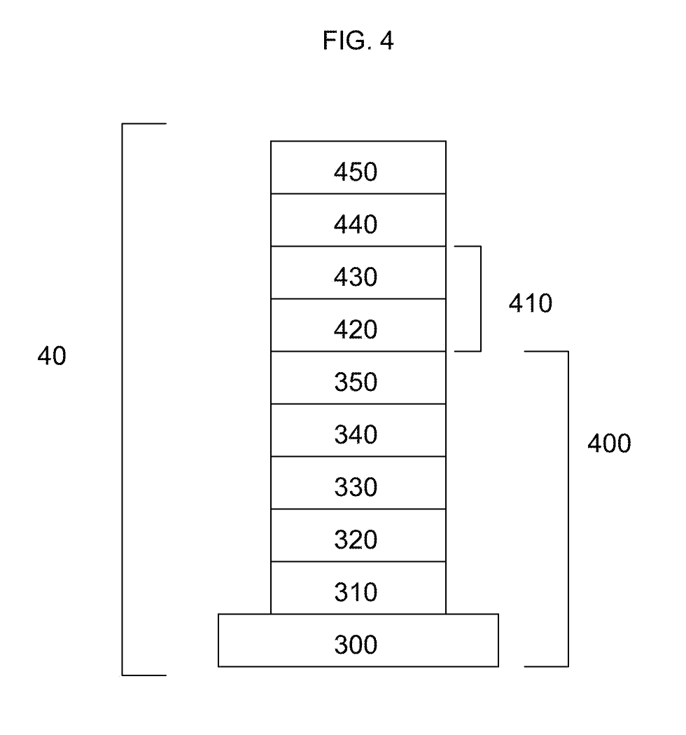

Transparent conductive oxide layer 330 can be deposited adjacent to second barrier layer 320. Transparent conductive oxide layer 330 can be deposited using any known deposition technique, including sputtering. Transparent conductive oxide layer 330 can include a layer including cadmium and tin and can have any suitable thickness. For example, transparent conductive oxide layer 330 can have a thickness of about 100 nm to about 1000 nm. A control layer 340 can be deposited adjacent to transparent conductive oxide layer 330 to enable proper transformation of transparent conductive oxide layer 330. Control layer 340 can be deposited using any known deposition technique, including sputtering. Control layer 340 can include a tin oxide and can be of any suitable thickness. For example, control layer 340 can have a thickness of about 10 nm to about 100 nm. A buffer layer 350 can be deposited adjacent to control layer 340 to facilitate proper deposition of semiconductor window layer 420 from FIG. 4. Buffer layer 350 can be deposited using any known deposition technique, including sputtering. Buffer layer 350 can include a tin(IV) oxide and can be of any suitable thickness. For example, buffer layer 350 can have a thickness of about 10 nm to about 100 nm.

Transparent conductive oxide stack 360 from FIG. 3 can be annealed to form annealed transparent conductive oxide stack 400 from FIG. 4. Transparent conductive oxide stack 360 can be annealed using any suitable annealing process. The annealing can occur in the presence of a gas selected to control an aspect of the annealing, for example nitrogen gas. Transparent conductive oxide stack 360 can be annealed under any suitable pressure, for example, under reduced pressure, in a low vacuum, or at about 0.01 Pa (10⁻⁴ Ton). Transparent conductive oxide stack 360 can be annealed at any suitable temperature or temperature range. For example, transparent conductive oxide stack 360 can be annealed at about 400° C. to about 800° C. Transparent conductive oxide stack 360 can be annealed at about 500° C. to about 700° C. Transparent conductive oxide stack 360 can be annealed for any suitable duration. Transparent conductive oxide stack 360 can be annealed for about 10 to about 25 minutes. Transparent conductive oxide stack 360 can be annealed for about 15 to about 20 minutes.

Annealed transparent conductive oxide stack 400 can be used to form photovoltaic device 40 from FIG. 4. Referring to FIG. 4, a semiconductor bi-layer 410 can be deposited adjacent to annealed transparent conductive oxide stack 400. Semiconductor bi-layer 410 can include a semiconductor window layer 420 and a semiconductor absorber layer 430. Semiconductor window layer 420 can be deposited adjacent to annealed transparent conductive oxide stack 400. Semiconductor window layer 420 can be deposited using any known deposition technique, including vapor transport deposition. Semiconductor absorber layer 430 can be deposited adjacent to semiconductor window layer 420. Semiconductor absorber layer 430 can be deposited using any known deposition technique, including vapor transport deposition. Semiconductor window layer 420 can include a cadmium sulfide layer. Semiconductor absorber layer 430 can include a cadmium telluride layer. A back contact 440 can be deposited adjacent to semiconductor bi-layer 410. Back contact 440 can be deposited adjacent to semiconductor absorber layer 430. A back support 450 can be deposited adjacent to back contact 440.

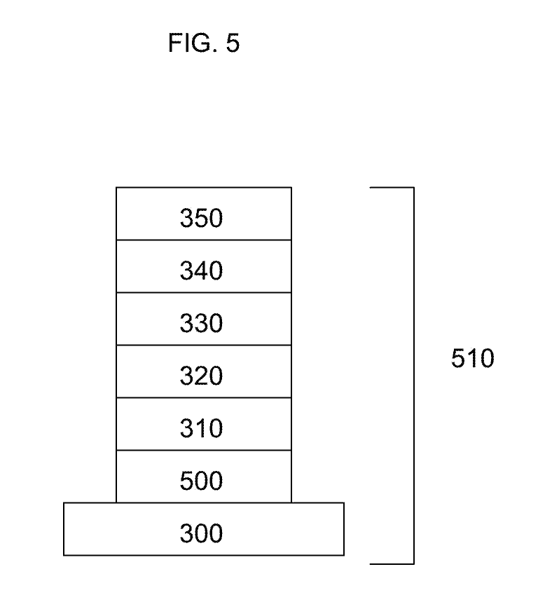

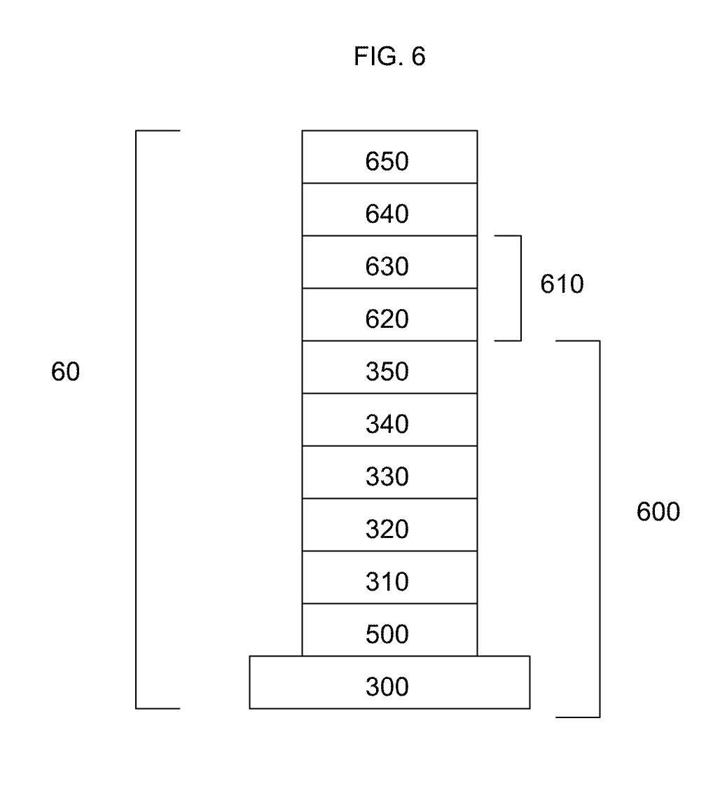

FIG. 5 shows an embodiment, in which first barrier layer 310 can be deposited adjacent to an additional barrier layer 500. First barrier layer 310 can be deposited using any known deposition technique, including sputtering. Second barrier layer 320 can be deposited onto first barrier layer 310. Second barrier layer 320 can be deposited using any known deposition technique, including sputtering. First barrier layer 310 can include a silicon nitride or an aluminum-doped silicon nitride. Second barrier layer 320 can include a silicon oxide or an aluminum-doped silicon oxide. Additional barrier layer 500 can include any suitable barrier material, including a silicon oxide, silicon nitride, aluminum-doped silicon oxide, or aluminum-doped silicon nitride. Transparent conductive oxide stack 510 can include any suitable number of additional barrier layers 500. According to one embodiment, a first silicon oxide can be deposited onto a silicon nitride, and the silicon nitride can be deposited onto a second silicon oxide; the second silicon oxide can be deposited onto a substrate. Alternatively, a first aluminum-doped silicon oxide can be deposited onto an aluminum-doped silicon nitride, and the aluminum-doped silicon nitride can be deposited onto a second aluminum-doped silicon oxide; the second aluminum-doped silicon oxide can be deposited onto a substrate. Transparent conductive oxide layer 330 can be deposited adjacent to second barrier layer 320. Transparent conductive oxide layer 330 can be deposited using any known deposition technique, including sputtering. Transparent conductive oxide layer 330 can include a layer including cadmium and tin. Control layer 340 can be deposited adjacent to transparent conductive oxide layer 330 to enable proper transformation of transparent conductive oxide layer 330. Control layer 340 can be deposited using any known deposition technique, including sputtering. Control layer 340 can include a tin oxide. Buffer layer 350 can be deposited adjacent to control layer 340 to facilitate proper deposition of semiconductor window layer 630 from FIG. 6. Buffer layer 350 can be deposited using any known deposition technique, including sputtering. Substrate 300, additional barrier layer(s) 500, first barrier layer 310, second barrier layer 320, transparent conductive oxide layer 330, control layer 340, and buffer layer 350 can form transparent conductive oxide stack 510. Transparent conductive oxide stack 510 from FIG. 5 can be annealed to form annealed transparent conductive oxide stack 600 from FIG. 6.

Annealed transparent conductive oxide stack 600 can be used to form photovoltaic device 60 from FIG. 6. Semiconductor bi-layer 610 can be deposited adjacent to annealed transparent conductive oxide stack 600. Semiconductor bi-layer 610 can include semiconductor window layer 620 and semiconductor absorber layer 630. Semiconductor window layer 620 can include a cadmium sulfide layer and can be deposited via any suitable deposition technique, including vapor transport deposition. Semiconductor absorber layer 630 can include a cadmium telluride layer and can be deposited adjacent to semiconductor window layer 620. Semiconductor absorber layer 630 can be deposited using any known deposition technique, including vapor transport deposition. A back contact 640 can be deposited adjacent to semiconductor bi-layer 610. Back contact 640 can be deposited adjacent to semiconductor absorber layer 630. A back support 650 can be deposited adjacent to back contact 640.

In one experiment, two sets of transparent conductive oxide stacks were formed consistent with two of the preferred embodiments. The first configuration consisted of: 75 nm tin(IV) oxide; 25 nm tin oxide; 250 nm cadmium stannate; 30 nm aluminum-doped silicon oxide; 30 nm aluminum-doped silicon nitride; and glass. The second configuration consisted of: 75 nm tin(IV) oxide; 25 nm tin oxide; 250 nm cadmium stannate; 100 nm aluminum-doped silicon nitride; and glass. Results indicated that stacks formed consistent with the first configuration were highly resistive, whereas stacks formed consistent with the second configuration were not, underscoring the necessity for a post-sputtering annealing process to transform the stacks.

In a subsequent experiment, stacks formed according to the same configurations were annealed in a belt furnace in a low vacuum (nitrogen annealing would have achieved similar results). Nearly all of the stacks demonstrated desirable sheet resistance (less than 10 ohms/sq). Results also indicated that the stacks which included the barrier bi-layer of 30 nm aluminum-doped silicon nitride and 30 nm aluminum-doped silicon oxide performed better in reducing reflection loss and interference. In a similar experiment, the same stack configurations were annealed in a belt furnace in the presence of a nitrogen gas. Results indicated low sheet resistance (most between 5-9 ohms/sq), as well as desired absorption and transmission percentages. Results also indicated that the stacks which included the barrier bi-layer of 30 nm aluminum-doped silicon nitride and 30 nm aluminum-doped silicon oxide performed better in reducing reflection loss and interference.

In another experiment, stacks were formed according to the following configuration: 75 nm tin(IV) oxide; 25 nm tin oxide; 250 nm cadmium stannate; 30 nm aluminum-doped silicon oxide; 30 nm aluminum-doped silicon nitride; and glass. The stacks were annealed in a belt furnace with a low vacuum of about 0.01 Pa (10⁻⁴ Ton). Cadmium sulfide and cadmium telluride layers were deposited onto the stacks using vapor transport deposition. A device formed with the aforementioned stack configuration had smooth cadmium sulfide distribution, likely a result of proper application of the preceding buffer layer. Subsequent analysis indicated that the devices performed well, with average efficiency in the 10-12% range and fill factor in the 65-75% range.

Photovoltaic devices/cells fabricated using the methods discussed herein may be incorporated into one or more photovoltaic modules, each of which may include one or more submodules. Such modules may by incorporated into various systems for generating electricity. For example, a photovoltaic cell may be illuminated with a beam of light to generate a photocurrent. The photocurrent may be collected and converted from direct current (DC) to alternating current (AC) and distributed to a power grid. Light of any suitable wavelength may be directed at the cell to produce the photocurrent, including, for example, more than 400 nm, or less than 700 nm (e.g., ultraviolet light). Photocurrent generated from one photovoltaic cell may be combined with photocurrent generated from other photovoltaic cells. For example, the photovoltaic cells may be part of one or more photovoltaic modules in a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method for manufacturing a multi-layered structure, the method comprising:
annealing a stack, wherein the annealing comprises heating the stack in the presence of an inert gas, and the stack comprises a layer including cadmium and tin.

2. The method of claim 1, further comprising depositing the layer including cadmium and tin on a substrate.

3. The method of claim 1, wherein the inert gas comprises at least one gas selected from the group consisting of forming gas, hydrogen gas, nitrogen gas, a hydrogen and nitrogen gas mix, and argon gas.

4. The method of claim 1, further comprising forming a stack, wherein the forming comprises:
depositing one or more barrier layers on a substrate;
depositing the layer including cadmium and tin on the one or more barrier layers; and
depositing a buffer layer on the layer including cadmium and tin.

5. The method of claim 4, further comprising depositing a control layer on the layer including cadmium and tin prior to depositing a buffer layer.

6. The method of claim 4, wherein the depositing comprises sputtering.

7. The method of claim 6, wherein the sputtering comprises DC sputtering or AC dual magnetron sputtering.

8. The method of claim 4, wherein the forming occurs under about 2 to 7 mtorr of pressure or in a vacuum.

9. The method of claim 4, wherein the annealing further comprises heating the stack for about 3 to about 25 minutes at about 500 to 700 C.

10. The method of claim 4, wherein the heating comprises radiated heating, convective heating, or resistive heating.

11. The method of claim 4, wherein depositing one or more barrier layers comprises:
depositing a silicon nitride directly on a substrate;
depositing a silicon oxide;
depositing an aluminum-doped silicon nitride directly on a substrate;
depositing an aluminum-doped silicon oxide;
depositing a silicon nitride directly on a substrate and a silicon oxide on the silicon nitride; or
depositing an aluminum-doped silicon nitride directly on a substrate and an aluminum-doped silicon oxide on the aluminum-doped silicon nitride.

12. The method of claim 4, wherein depositing one or more barrier layers comprises:
depositing a first silicon oxide on a substrate;
depositing a silicon nitride on the first silicon oxide; and
depositing a second silicon oxide on the silicon nitride.

13. The method of claim 4, wherein depositing one or more barrier layers comprises:
depositing a first aluminum-doped silicon oxide on a substrate;
depositing an aluminum-doped silicon nitride on the first aluminum-doped silicon oxide; and
depositing a second aluminum-doped silicon oxide on the aluminum-doped silicon nitride.

14. The method of claim 5, wherein:
each of the one or more barrier layers is selected from the group consisting of silicon nitride, aluminum-doped silicon nitride, silicon oxide, aluminum-doped silicon oxide, boron-doped silicon nitride, phosphorous-doped silicon nitride, silicon oxide-nitride, and tin oxide;
the buffer layer is selected from the group consisting of zinc tin oxide, tin oxide, zinc oxide, and zinc magnesium oxide; or the control layer comprises a tin oxide.

15. The method of claim 1, further comprising depositing a cadmium sulfide layer on the stack, and a cadmium telluride layer on the cadmium sulfide layer.

16. A multilayered structure comprising:
a stack of one or more layers comprising a transparent conductive oxide layer, wherein the stack is annealed in the presence of an inert gas, and wherein the transparent conductive oxide layer comprises a layer including cadmium and tin.

17. The multilayered structure of claim 16, wherein the stack further comprises a substrate, one or more barrier layers, and a buffer layer, wherein each of the one or more barrier layers is positioned above the substrate, the transparent conductive oxide layer is positioned above the one or more barrier layers, and the buffer layer is positioned above the transparent conductive oxide layer.

18. The multilayered structure of claim 17, wherein:
the buffer layer is selected from the group consisting of zinc tin oxide, tin oxide, zinc oxide, and zinc magnesium oxide; or
each of the one or more barrier layers is selected from the group consisting of silicon nitride, aluminum-doped silicon nitride, silicon oxide, aluminum-doped silicon oxide, boron-doped silicon nitride, phosphorous-doped silicon nitride, silicon oxide-nitride, and tin oxide.

19. The multilayered structure of claim 16, further comprising a cadmium sulfide layer on the stack, and a cadmium telluride layer on the cadmium sulfide layer.

20. A multilayered structure comprising:
a substrate; and
an amorphous layer including cadmium and tin on the substrate, wherein the stack has a sheet resistance of more than about 100 ohms/sq or less than about 20 ohms/sq.
